(19) United States
(12) Patent Application Publication
(10) Pub. No.: US 2007/0158793 A1
(43) Pub. Date: Jul. 12, 2007

(54) CARRIER STRUCTURE FOR SEMICONDUCTOR PACKAGE

(75) Inventor: SHIH-LUNG HUANG, Chu-Nan (TW)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: ALTUS TECHNOLOGY INC., Miao-Li Hsien (TW)

(21) Appl. No.: 11/309,812

(22) Filed: Oct. 2, 2006

(30) Foreign Application Priority Data
Dec. 30, 2005 (CN) 200510121414.0

(51) Int. Cl. H01L 23/495

(52) U.S. Cl. 257/666

(57) ABSTRACT

An exemplary carrier structure (20) for carrying workpieces includes a body (23) and an adhesive tape (27). The body defines a receiving hole (21) therethrough for receiving one or more of the workpieces therein. The adhesive tape is attached to one side of the body and covers the receiving hole thereby allowing one or more of the workpieces to be received in the receiving hole and on the adhesive tape.

### FIELD OF THE INVENTION

The present invention generally relates to carriers in pipelining and, more particularly, to a carrier structure configured (i.e., structured and arranged) for carrying workpieces in semiconductor packaging processes.

### DESCRIPTION OF RELATED ART

In semiconductor packaging processes, workpieces such as chips, base boards, package bodies, or the like usually need to be used many times, for example punching, bonding and incising. In order to improve efficiency, carrier structures are used for carrying workpieces in pipelining.

A typical carrier structure for carrying workpieces is a thin board made of metal. The carrier structure defines a plurality of receiving holes therethrough. A supporting plate extends from the board into each corner of each receiving hole. A positioning tab is punched perpendicularly in each supporting plate. The receiving holes are engaged with the workpieces so that the workpieces are supported on the supporting plates and are held in position by the positioning tabs. Thus the workpieces are transmitted by the carrier structure in pipelining. However, such a carrier structure is designed for a certain workpiece. That is, when the size of the workpiece is changed, a new carrier structure is needed. In addition, the positioning tab is perpendicular relative to the supporting plate. When the workpieces are placed on or removed from the carrier structure the positioning tabs can potentially damage the workpieces.

Therefore, a new carrier structure is desired in order to overcome the above-described shortcomings.

### SUMMARY OF THE INVENTION

In one embodiment thereof, a carrier structure for carrying workpieces includes a body and an adhesive tape. The body has a receiving hole defined therethrough for receiving one or more of the workpieces therein. The adhesive tape is attached to one side of the body and covers the receiving hole thereby allowing one or more of the workpieces to be received in the receiving hole and on the adhesive tape.

Other advantages and novel features of the embodiments will become more apparent from the following detailed description thereof when taken in conjunction with the accompanying drawings.

### BRIEF DESCRIPTION OF THE DRAWINGS

Many aspects of the present carrier structure can be better understood with reference to the following drawings. The components in the drawings are not necessarily drawn to scale, the emphasis instead being placed upon clearly illustrating the principles of the carrier structure and its potential applications. Moreover, in the drawings, like reference numerals designate corresponding parts throughout the several views.

FIG. 1 is a schematic view of a carrier structure in accordance with a first preferred embodiment of the present invention;

FIG. 2 is a cut-away view of the carrier structure along line II-II in FIG. 1;

FIG. 3 is a schematic view of a carrier structure in accordance with a second preferred embodiment of the present invention;

FIG. 4 is a schematic view of a carrier structure in accordance with a third preferred embodiment of the present invention;

FIG. 5 is a schematic view of a carrier structure in accordance with a fourth preferred embodiment of the present invention; and

FIG. 6 is a schematic view of a carrier structure in accordance with a fifth preferred embodiment of the present invention.

### DETAILED DESCRIPTION OF THE EMBODIMENTS

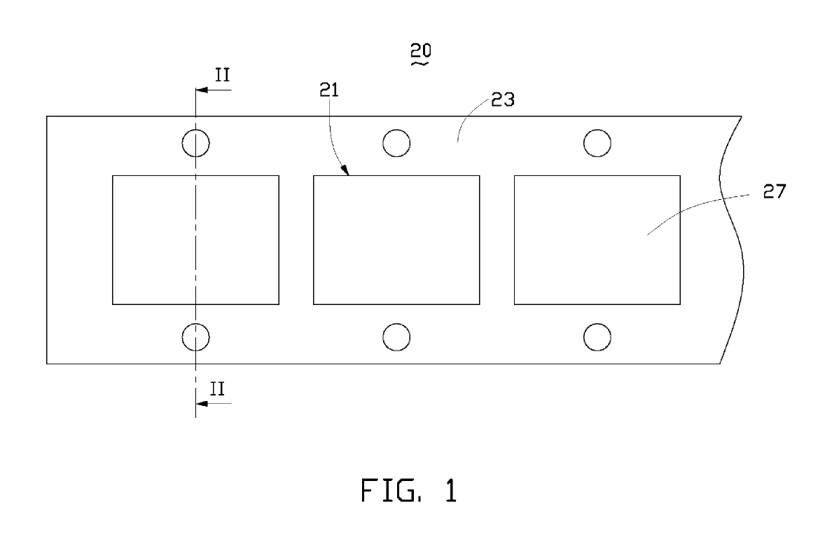

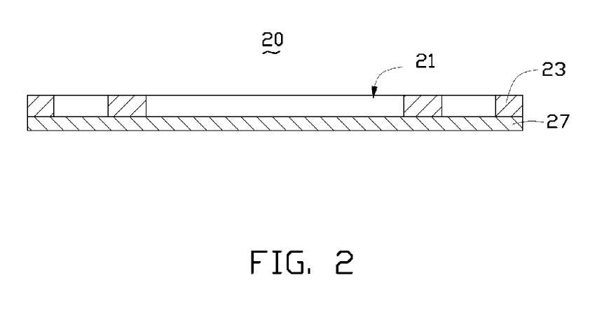

Referring now to the drawings in detail, FIGS. 1-2 show a carrier structure 20 of a first preferred embodiment of the present invention. The carrier structure 20, in the illustrated embodiment, is configured for carrying workpieces in pipelining in semiconductor packaging processes. The workpieces may be chips, base boards, package bodies, or the like. It is to be understood that the carrier structure 20 or obvious variations thereof may prove useful in other work environments as well. The carrier structure 20 includes a body 23 and an adhesive tape 27. The adhesive tape 27 is attached to one side of the body 23.

The body 23 is a substantially thin board in shape and is made of a hard material produced by anodic oxidation, such as stainless steel and aluminium alloy. The body 23 may be formed by a single punching process. A plurality of receiving holes 21 are defined through the body 23. The receiving holes 21 are rectangular in shape and are aligned along a line in the body 23. The size of each receiving hole 21 may be larger than the size of the workpiece thus allowing the workpiece to be received in the receiving hole 21.

The adhesive tape 27 is made of a flexible material capable of resisting high temperature such as polyimide. A glue layer of the adhesive tape 27 is made of silicone. The adhesive tape 27 is attached to one side of the body 23 and covers the receiving holes 21. The glue layer of the adhesive tape 27 contacts the body 23.

In use, the workpieces are received in the receiving holes 21 and on the adhesive tape 27. The workpieces are held on the carrier structure 20 due to the glue layer of the adhesive tape 27. Thus the transmitting rate can be increased and the efficiency can be improved.

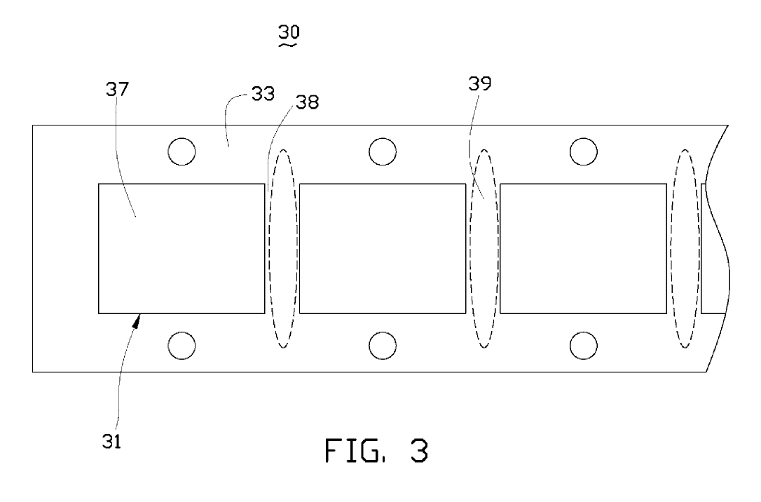

Also referring to FIG. 3, a carrier structure 30 of a second preferred embodiment of the present invention is shown. The carrier structure 30 is similar to the carrier structure 20 and includes a body 33 and an adhesive tape 37. A plurality of receiving holes 31 are defined through the body 33 thereby forming a plurality of connecting portions 38 between two adjacent receiving holes 31. The adhesive tape 37 attached to the connecting portion 38 defines an elliptic hole 39 therein. The elliptic hole 39 can increase the breaking tension of the adhesive tape 37. It is to be understood that the hole 39 may have an alternative shape such as a rounded shape.

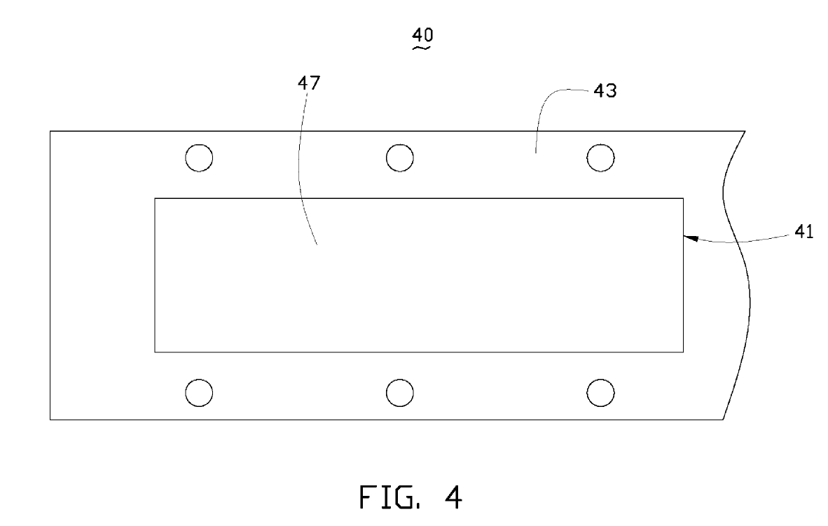

Also referring to FIG. 4, a carrier structure 40 of a third preferred embodiment of the present invention is shown. The carrier structure 40 is similar to the carrier structure 20 and includes a body 43 and an adhesive tape 47. One receiving hole 41 is defined through the body 43. The adhesive tape 47 is attached to the body 43 and covers the receiving hole 41. A plurality of workpieces can be arrayed in the receiving hole 41 and on the adhesive tape 47.

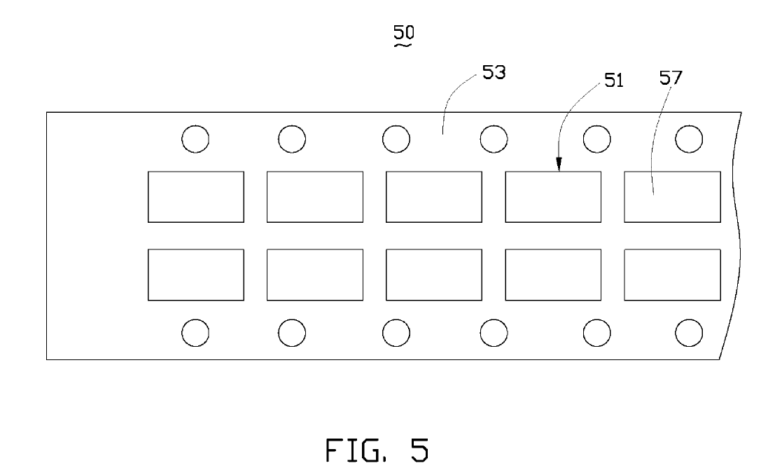

Also referring to FIG. 5, a carrier structure 50 of a fourth preferred embodiment of the present invention is shown. The carrier structure 50 is similar to the carrier structure 20 and includes a body 53 and an adhesive tape 57. A plurality of receiving holes 51 are defined through the body 53. The adhesive tape 57 is attached to the body 53 and covers the receiving holes 51. The receiving holes 51 are aligned along two lines in the body 53. It is to be understood that the number and the size of the receiving holes can be chosen according to the number, the size, and the arrangement of the workpieces.

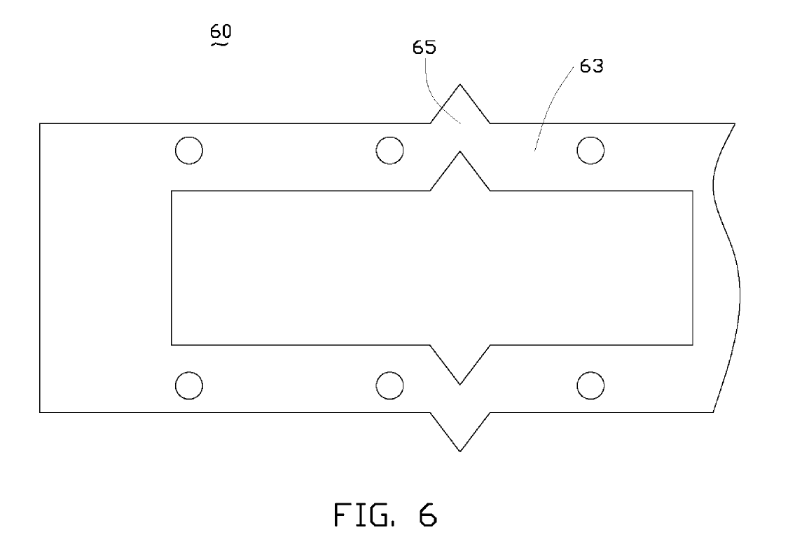

Also referring to FIG. 6, a carrier structure 60 of a fifth preferred embodiment of the present invention is shown. The carrier structure 60 is similar to the carrier structure 20 and includes a body 63. The body 63 has a plurality of V-shaped bent portions 65. The bent portions 65 can increase the breaking tension of the body 63. It is to be understood that the bent portion 65 may be of an alternative shape such as arcuate.

It is to be understood, however, that even though numerous characteristics and advantages of the present embodiments have been set forth in the foregoing description, together with details of the structures and functions of the embodiments, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A carrier structure configured for carrying workpieces, comprising: a body defining a receiving hole therethrough, the receiving hole being configured for receiving one or more of the workpieces therein; and an adhesive tape attached to one side of the body and covering the receiving hole thereby allowing the one or more of the workpieces to be received in the receiving hole and on the adhesive tape.

2. The carrier structure as claimed in claim 1, wherein the body is a substantially thin board in shape.

3. The carrier structure as claimed in claim 1, wherein the body is made of a hard material produced by anodic oxidation.

4. The carrier structure as claimed in claim 3, wherein the body is made of a material selected from a group consisting of stainless steel and aluminium alloy.

5. The carrier structure as claimed in claim 1, wherein the body has a bent portion configured for increasing the breaking tension of the body.

6. The carrier structure as claimed in claim 5, wherein the bent portion is V-shaped.

7. The carrier structure as claimed in claim 1, further comprising a plurality of other receiving holes defined through the body thereby forming a plurality of connecting portions between two adjacent receiving holes.

8. The carrier structure as claimed in claim 7, wherein the adhesive tape attached to the connecting portion defines an elliptic hole therein.

9. The carrier structure as claimed in claim 7, wherein the receiving holes are aligned along a line in the body.

10. The carrier structure as claimed in claim 7, wherein the receiving holes are aligned along two lines in the body.

11. The carrier structure as claimed in claim 1, wherein the adhesive tape is made of a flexile material capable of resisting high temperature.

12. The carrier structure as claimed in claim 1, wherein the adhesive tape is made of polyimide.

13. The carrier structure as claimed in claim 1, wherein a glue layer of the adhesive tape is made of silicone.
